(19) United States
(12) Patent Application Publication
(10) Pub. No.: US 2016/0299420 A1
(43) Pub. Date: Oct. 13, 2016

(54) MASK, MANUFACTURING METHOD THEREOF AND EXPOSURE APPARATUS

(71) Applicants: BOE TECHNOLOGY GROUP CO., LTD., Beijing (CN); HEFEI BOE OPTOELECTRONICS TECHNOLOGY CO., LTD., Hefei (CN)

(72) Inventor: Man WANG, Beijing (CN)

(21) Appl. No.: 15/079,289

(22) Filed: Mar. 24, 2016

(30) Foreign Application Priority Data
Apr. 13, 2015 (CN) 201510172699.4

(51) Int. Cl. G03F 1/50

(52) U.S. Cl. CPC G03F 1/50

(57) ABSTRACT

The present invention provides a mask, comprising a base substrate, a first mask pattern formed on an upper surface of the base substrate, and a second mask pattern formed on a lower surface of the base substrate. Each of the first and second mask patterns comprises a light transmissive region and a light blocking region. A projection of the light transmissive region of the first mask pattern on a plane where the second mask pattern is located is outside the light blocking region of the second mask pattern, and the light blocking region of the second mask pattern can block at least part of light diffracted at a boundary between the light blocking region and the light transmissive region of the first mask pattern, to prevent the at least part of light from emitting from the light transmissive region of the second mask pattern.

### CROSS-REFERENCE TO RELATED APPLICATIONS

The present application claims the priority of Chinese Patent Application No. 201510172699.4, filed on Apr. 13, 2015, the contents of which are incorporated herein in their entirety by reference.

### FIELD OF THE INVENTION

The present invention relates to the field of display technology, and in particular, relates to a mask, a manufacturing method of the mask, and an exposure apparatus.

### BACKGROUND OF THE INVENTION

In the field of display technology, structures, such as a thin film transistor, various signal lines, a pixel electrode, and the like, in a display device are manufactured by a photolithography process. The photolithography process generally includes steps of priming, coating a photoresist, exposing, developing, etching, stripping off the remaining photoresist, and the like, and among others, the step of exposing is performed by an exposure apparatus.

FIG. 1 shows a mask used in an exposure apparatus in the prior art. As shown in FIG. 1, a mask 1 includes a base substrate 10, and a light blocking layer 11 is formed on a surface (e.g., a lower surface of the base substrate 10 as shown in FIG. 1) of the base substrate 10. The light blocking layer 11 covers partial regions of the base substrate 10, so that the mask 1 has light blocking regions a1 corresponding to the light blocking layer 11 and light transmissive regions b1 corresponding to the regions not covered by the light blocking layer 11. During an exposure process performed on a photoresist, the mask 1 is spaced apart from a substrate on which the photoresist is coated by a certain distance, the exposure apparatus is placed right above the mask 1, and the substrate on which the photoresist is coated is placed right below the mask 1. A light source in the exposure apparatus emits light towards the mask 1, and part of the light passes through the light transmissive regions b1 and irradiates onto the photoresist, to expose the photoresist in the corresponding regions of the substrate.

In the ideal case, a size of each of exposed regions of the photoresist is consistent with that of the light transmissive region b1 corresponding thereto. However, due to a diffraction effect of light, a part of the photoresist corresponding to a certain light blocking region a1 is irradiated by light, and an intensity of the light irradiating thereon is strong enough to expose the part of the photoresist, which causes an actual size of each of the exposed regions of the photoresist to be greater than that of the light transmissive region b1 corresponding thereto, as shown in FIG. 1. Specifically, in a case where a photoresist used in the exposure process is a negative photoresist, an exposed region corresponds to a pattern, and an increase in size of the exposed region will cause a size of the pattern corresponding to the exposed region to increase accordingly (however, it is desired that a size of the pattern is equal to that of the corresponding light transmissive region b1). In a case where a photoresist used in the exposure process is a positive photoresist, an exposed region corresponds to an interval region between two adjacent patterns, and an increase in size of the exposed region will cause a size of the corresponding interval region between two adjacent patterns to increase accordingly (however, it is desired that a size of an interval region between two adjacent patterns is equal to that of the corresponding light transmissive region b1). It can be seen that, the above mask cannot realize the refinement of an exposure process, and limits the accuracy of sizes of a thin film transistor and various signal lines in a display device, thus being unfavorable for improving a pixel density of the display device.

### SUMMARY OF THE INVENTION

In order to solve at least one of the technical problems existing in the prior art, the present invention provides a mask, a manufacturing method of the mask, and an exposure apparatus. The mask can allow a size of an exposed region of a photoresist to be closer to that of a light transmissive region of the mask, and make a pattern obtained after development finer, and thus facilitate further refinement of an exposure process.

In order to achieve the object of the present invention, there is provided a mask, comprising a base substrate; a first mask pattern formed on an upper surface of the base substrate; and a second mask pattern formed on a lower surface of the base substrate; wherein, the first mask pattern comprises a light transmissive region and a light blocking region, the second mask pattern comprises a light transmissive region and a light blocking region, a projection of the light transmissive region of the first mask pattern on a plane where the second mask pattern is located is outside the light blocking region of the second mask pattern, and the light blocking region of the second mask pattern is capable of blocking at least part of light diffracted at a boundary between the light blocking region and the light transmissive region of the first mask pattern, to prevent the at least part of light from emitting from the light transmissive region of the second mask pattern.

In the mask, the projection of the light transmissive region of the first mask pattern on the plane where the second mask pattern is located coincides with the light transmissive region of the second mask pattern.

In the mask, both the first mask pattern and the second mask pattern are formed by a photolithography process.

In the mask, the light blocking region of the first mask pattern has a low light reflectivity, or the light blocking region of the second mask pattern has a low light reflectivity.

Further, in the mask, both the light blocking region of the first mask pattern and the light blocking region of the second mask pattern have a low light reflectivity.

In the mask, both the light blocking region of the first mask pattern and the light blocking region of the second mask pattern are made of a metal oxide.

Further, in the mask, both the light blocking region of the first mask pattern and the light blocking region of the second mask pattern are made of chromium oxide.

As another technical solution of the present invention, the present invention further provides a manufacturing method of the above mask, and the manufacturing method comprises steps of:

forming a first mask pattern on a surface of a base substrate, such that the first mask pattern comprises a light transmissive region and a light blocking region; and

forming a second mask pattern on an opposite surface of the base substrate opposite to the surface where the first mask pattern is located, such that the second mask pattern comprises a light transmissive region and a light blocking region, and a projection of the light transmissive region of the first mask pattern on a plane where the second mask pattern is located being outside the light blocking region of the second mask pattern.

In the manufacturing method, the projection of the light transmissive region of the first mask pattern on the plane where the second mask pattern is located coincides with the light transmissive region of the second mask pattern.

As another technical solution of the present invention, the present invention further provides an exposure apparatus comprising the above mask provided by the present invention.

The beneficial technical effects of the present invention are as follows.

The mask provided by the present invention has the first mask pattern on its upper surface and the second mask pattern on its lower surface, and can reduce an amount by which a size of an actually exposed region of a photoresist exceeds a size of the light transmissive region of the mask, thereby allowing a size of an exposed region of a photoresist to be closer to that of the light transmissive region of the mask, making a pattern obtained after development finer, and facilitating further refinement of an exposure process.

The mask manufactured by the manufacturing method provided by the present invention can reduce an amount by which a size of an actually exposed region of a photoresist exceeds a size of the light transmissive region of the mask, thereby allowing a size of an exposed region of a photoresist to be closer to that of the light transmissive region of the mask, making a pattern obtained after development finer, and facilitating further refinement of an exposure process.

The exposure apparatus provided by the present invention includes the mask provided by the present invention, and thus can reduce an amount by which a size of an actually exposed region of a photoresist exceeds a size of the light transmissive region of the mask, thereby allowing a size of an exposed region of a photoresist to be closer to that of the light transmissive region of the mask, making a pattern obtained after development finer, and facilitating further refinement of an exposure process.

### BRIEF DESCRIPTION OF THE DRAWINGS

The accompanying drawings are used for providing a further understanding of the present invention, and constitute a part of the specification. The accompanying drawings, together with the following embodiments, are only used for explaining the present invention, but are not intended to limit the scope of the present invention. In the drawings:

FIG. 1 is a schematic diagram of a mask in the prior art;

FIG. 2 is a schematic diagram of a mask provided by a first embodiment of the present invention;

FIG. 3 is a schematic diagram showing that light passes through the mask as shown in FIG. 2 to expose a photoresist;

FIG. 4 is a schematic diagram of a mask provided by a second embodiment of the present invention; and

FIG. 5 is a schematic diagram showing that light passes through the mask as shown in FIG. 4 to expose a photoresist.

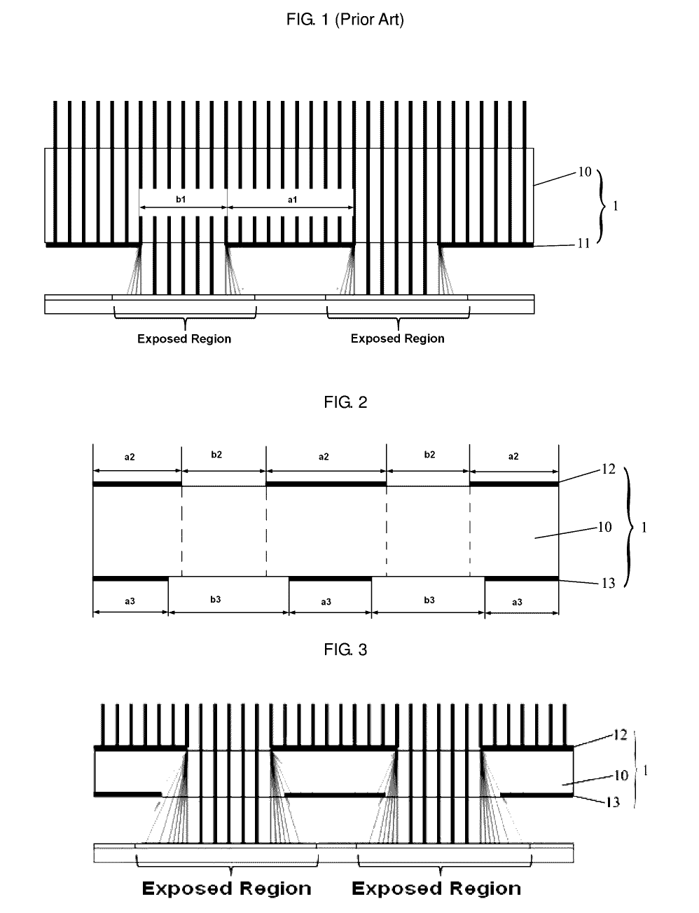

### REFERENCE SIGNS

1: mask; 10: base substrate; 11: light blocking layer; 12: first mask pattern; 13: second mask pattern; a1, a2, a3 and a4: light blocking region; b1, b2, b3 and b4: light transmissive region.

### DETAILED DESCRIPTION OF THE EMBODIMENTS

Embodiments of the present invention will be described below in detail with reference to the accompanying drawings. It should be understood that, the embodiments described herein are only used for describing and explaining the present invention, but are not intended to limit the scope of the present invention.

It should be noted that, the singular forms “a,” “an,” and “the” used in the present application are intended to include the plural forms as well, unless the context clearly indicates otherwise.

The present invention provides multiple embodiments of a mask, which will be described in detail below.

FIG. 2 is a schematic diagram of a mask provided by a first embodiment of the present invention. As shown in FIG. 2, in the present embodiment, the mask 1 includes a base substrate 10, a first mask pattern 12 formed on an upper surface of the base substrate 10, and a second mask pattern 13 formed on a lower surface of the base substrate 10. In this case, it should be understood that, the lower surface of the base substrate 10 is an opposite surface opposite to the surface where the first mask pattern is located (i.e., the upper surface of the base substrate 10). The first mask pattern 12 includes light transmissive regions b2 and light blocking regions a2, and the second mask pattern 13 includes light transmissive regions b3 and light blocking regions a3. Further, a projection of each light transmissive region b2 of the first mask pattern 12 on a plane where the second mask pattern 13 is located is outside a corresponding light blocking region a3 of the second mask pattern 13, and within a corresponding light transmissive region b3 of the second mask pattern 13. That is, each light transmissive region b2 of the first mask pattern 12 corresponds to a light transmissive region b3 of the second mask pattern 13, and a light transmissive region b3 of the second mask pattern 13 is larger than a corresponding light transmissive region b2 of the first mask pattern 12. Furthermore, each light blocking region a3 of the second mask pattern 13 is capable of blocking at least part of light diffracted at a boundary between a corresponding light blocking region a2 and a corresponding light transmissive region b2 of the first mask pattern 12, to prevent the at least part of light from emitting from the light transmissive region b3 of the second mask pattern 13.

In the present embodiment, in terms of each light blocking region a2 of the first mask pattern 12 and each light blocking region a3 of the second mask pattern 13, the term “light blocking” means that light transmittances of each light blocking region a2 of the first mask pattern 12 and each light blocking region a3 of the second mask pattern 13 is about 0.1% or less.

As shown in FIG. 3, in a case where a photoresist is exposed by using the mask 1 provided by the present embodiment, light will be diffracted when passing through the upper surface of the mask 1 and when passing through the lower surface of the mask 1, respectively.

Specifically, when irradiating onto the upper surface of the mask 1, light will be diffracted at an edge of each light blocking region a2 (i.e., an edge of each light transmissive region b2) of the first mask pattern 12. The propagation direction of part of the light irradiating onto the upper surface of the mask 1 will deviate outwards due to the diffraction, and this part of light irradiates onto a corresponding light blocking region a3 and a corresponding light transmissive region b3 of the second mask pattern 13 on the lower surface of the mask 1. Light irradiating onto a light blocking region a3 of the second mask pattern 13 is blocked by this light blocking region a3. The other part of light (other than said part of light) will keep the original propagation direction to irradiate onto the lower surface of the mask 1, and pass through a corresponding light transmissive region b3 of the second mask pattern 13 to irradiate onto a corresponding region of the photoresist.

When irradiating onto the lower surface of the mask 1, light will also be diffracted at an edge of each light blocking region a3 (i.e., an edge of each light transmissive region b3) of the second mask pattern 13. The propagation direction of part of light irradiating onto the lower surface of the mask 1 will deviate outwards due to the diffraction, and this part of light irradiates onto regions of the photoresist corresponding to a light blocking region a3 and/or a light transmissive region b3 of the second mask pattern 13 (depending on a size of each light blocking region a3 of the second mask pattern 13, specifically). Another part of light will be blocked by a corresponding light blocking region a3 of the second mask pattern 13, and the remaining part of light will keep the original propagation direction to irradiate onto a corresponding region of the photoresist.

In the present embodiment, light is diffracted when passing through the upper surface of the mask 1, and this diffraction causes part of light to irradiate onto light blocking regions a3 of the second mask pattern 13 on the lower surface of the mask 1. The light blocking regions a3 of the second mask pattern 13 block light irradiating thereon, to prevent the light irradiating thereon from emitting from light transmissive regions b3 of the second mask pattern 13 to corresponding regions of the photoresist. In this way, a reduced region of the photoresist corresponding to each light blocking region a2 of the first mask pattern 12 will be irradiated by light, and an intensity of light irradiating onto the region can be reduced. Thus, an amount by which a size of an exposed region of the photoresist exceeds a size of the light transmissive region b2 of the first mask pattern 12 can be reduced, and the size of an exposed region of the photoresist is closer to the size of the light transmissive region b2 of the first mask pattern 12 of the mask 1. Therefore, a pattern obtained after development is finer, which facilitates improvement of the accuracy of exposure and further refinement of an exposure process. This finally increases the pixel density of a display device.

From the foregoing description, it can be seen that, in the present embodiment, it is actually desired that the photoresist is exposed to have the same pattern as the first mask pattern 12, and the light blocking regions of the second mask pattern 13 are used for increasing the accuracy of exposure. As compared with the prior art, the first mask pattern 12 in the present embodiment is provided on the upper surface of the base substrate 10, and thus a distance between the first mask pattern 12 and a photoresist is larger. In this case, since light is diffracted at a boundary between the light blocking region a2 and the light transmissive region b2 of the first mask pattern 12, a size of regions of the photoresist irradiated by light becomes larger, which increases an amount of light irradiating onto a region of the photoresist corresponding to a light blocking region a2 of the first mask pattern 12. Thus, in practice, the second mask pattern 13 may be provided so that each light blocking region a3 thereof can block more light, and an amount of blocked light should be larger than an increased amount of light irradiating onto a region of the photoresist corresponding to each light blocking region a2 of the first mask pattern 12 due to an increased distance between the first mask pattern 12 and the photoresist. In this way, the light irradiating onto a region of the photoresist corresponding to each light blocking region a2 of the first mask pattern 12 has a smaller amount and a weaker intensity, and thus an improvement in accuracy of exposure as compared with the prior art can be obtained.

Both the first mask pattern 12 and the second mask pattern 13 can be formed by a photolithography process. Specifically, the first mask pattern 12 may be formed on a surface (e.g., the upper surface) of the base substrate 10 firstly, and then the second mask pattern 13 may be formed on another surface (e.g., the lower surface opposite to the upper surface) of the base substrate 10 after the first mask pattern 12 is formed.

Further, the first mask pattern 12 may be formed by the following method: in a first step, a layer of light blocking material is deposited on a surface (e.g., the upper surface) of the base substrate 10; in a second step, a photoresist is coated on the deposited light blocking material; in a third step, the coated photoresist is exposed and developed, so that some regions of the photoresist are removed and regions of the light blocking material corresponding to said regions of the photoresist are exposed; in a fourth step, the exposed regions of the light blocking material are etched; and in a fifth step, the remaining portions of the photoresist are stripped off. Finally, the desired first mask pattern 12 is obtained.

After the first mask pattern 12 is formed, the second mask pattern 13 may be formed by a similar method on another surface (e.g., the lower surface), which is an opposite surface opposite to the surface where the first mask pattern 12 is located, of the base substrate 10. For example, both the light blocking regions a2 of the first mask pattern 12 and the light blocking regions a3 of the second mask pattern 13 may be made of a metal oxide. Further, both the light blocking regions a2 of the first mask pattern 12 and the light blocking regions a3 of the second mask pattern 13 may be made of chromium oxide. Within a wave band of a light source used in an exposure apparatus, the light transmittance of chromium oxide is less than 0.1%, the light reflectivity of chromium oxide is about 10%. Thus, after light reflected by a material of chromium oxide two or more times, an intensity of the reflected light is close to zero.

In the present embodiment, optionally, each light blocking region a2 of the first mask pattern 12 has a low light reflectivity, or each light blocking region a3 of the second mask pattern 13 has a low light reflectivity. The expression “a low light reflectivity” used herein means a reflectivity of each light blocking region a2 of the first mask pattern 12 or each light blocking region a3 of the second mask pattern 13 is about 10% or less. With such a configuration, an intensity of light, which irradiates onto the lower surface of the mask 1 due to a first diffraction and is reflected to irradiate onto a region of the photoresist corresponding to a light blocking region a2 of the first mask pattern 12, can be reduced. As a result, a reduced region of the photoresist corresponding to each light blocking region a2 of the first mask pattern 12 is irradiated by light, and/or light with lowered intensity irradiates onto a region of the photoresist corresponding to each light blocking region a2 of the first mask pattern 12. Thus, an amount by which a size of an exposed region of the photoresist exceeds a size of the light transmissive region b2 of the first mask pattern 12 can be reduced, and the size of an exposed region of the photoresist is closer to that of the light transmissive region b2 of the first mask pattern 12 on the mask 1. Therefore, a pattern obtained after development is finer, which facilitates improvement of the accuracy of exposure and further refinement of an exposure process.

For example, in a case where each light blocking region a2 of the first mask pattern 12 has a low light reflectivity whereas each light blocking region a3 of the second mask pattern 13 has a high light reflectivity, after the light irradiating onto each light blocking region a3 of the second mask pattern 13 due to a first diffraction is reflected by the light blocking region a3 of the second mask pattern 13, a part of the light will irradiate onto a corresponding light blocking region a2 of the first mask pattern 12, and be significantly absorbed by the light blocking region a2 of the first mask pattern 12. However, the other part of the light will emit from a corresponding light transmissive region b2 of the first mask pattern 12, and thus will not have an influence on exposure of a photoresist. Thus, the light irradiating onto each light blocking region a3 of the second mask pattern 13 due to a first diffraction will not cause an irradiated region of a photoresist to be exposed, and especially will not cause a region of the photoresist corresponding to each light blocking region a2 of the first mask pattern 12 to be exposed.

As another example, in a case where each light blocking region a3 of the second mask pattern 13 has a low light reflectivity, the light irradiating onto each light blocking region a3 of the second mask pattern 13 due to a first diffraction will be directly absorbed by each light blocking region a3 of the second mask pattern 13 significantly. Thus, the light irradiating onto each light blocking region a3 of the second mask pattern 13 will not cause an irradiated region of a photoresist to be exposed, and especially will not cause a region of the photoresist corresponding to each light blocking region a2 of the first mask pattern 12 to be exposed.

Of course, both each light blocking region a2 of the first mask pattern 12 and each light blocking region a3 of the second mask pattern 13 may have a low light reflectivity (i.e., both a reflectivity of each light blocking region a2 of the first mask pattern 12 and a reflectivity of each light blocking region a3 of the second mask pattern 13 may be about 10% or less), and thus the light irradiating onto each light blocking region a3 of the second mask pattern 13 may be absorbed more completely. Thus, it is possible to prevent, to the greatest extent, the light irradiating onto each light blocking region a3 of the second mask pattern 13 due to a first diffraction from causing an irradiated region of a photoresist to be exposed, and especially from causing a region of the photoresist corresponding to each light blocking region a2 of the first mask pattern 12 to be exposed.

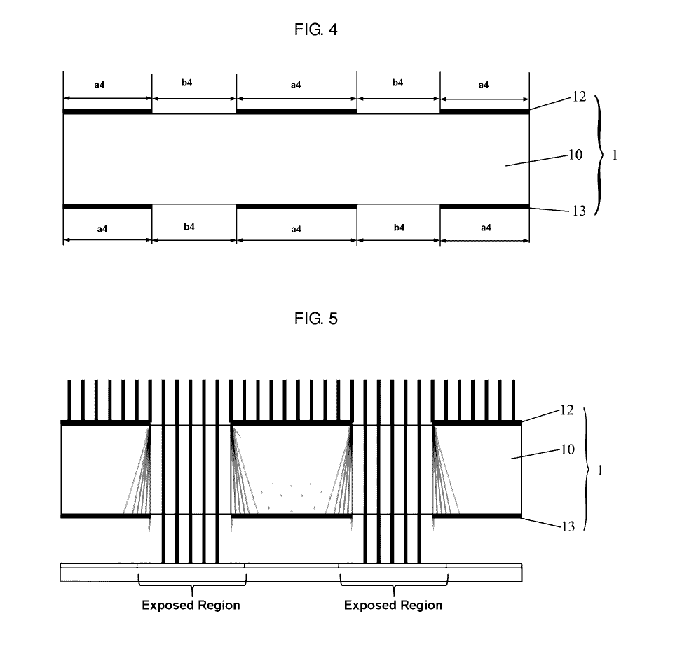

FIG. 4 is a schematic diagram of a mask provided by a second embodiment of the present invention. As shown in FIG. 4, in the present embodiment, a mask 1 includes a base substrate 10, a first mask pattern 12 formed on an upper surface of the base substrate 10, and a second mask pattern 13 formed on a lower surface of the base substrate 10. In this case, it should be understood that, the lower surface of the base substrate 10 is an opposite surface opposite to a surface where the first mask pattern is located (i.e., the upper surface of the base substrate 10). The first mask pattern 12 includes light transmissive regions b4 and light blocking regions a4, and the second mask pattern 13 includes light transmissive regions b4 and light blocking regions a4. Further, a projection of the light transmissive region b4 of the first mask pattern 12 on a plane where the second mask pattern 13 is located is outside a corresponding light blocking region a4 of the second mask pattern 13, and coincides with a corresponding light transmissive region b4 of the second mask pattern 13. Furthermore, each light blocking region a4 of the second mask pattern 13 is capable of blocking at least part of light diffracted at a boundary between the light blocking region a4 and the light transmissive region b4 of the first mask pattern 12, to prevent the at least part of light from emitting from a corresponding light transmissive region b4 of the second mask pattern 13.

In the present embodiment, the expression “light blocking” also means a light transmittance of each light blocking region a4 of the first mask pattern 12 and a light transmittance of each light blocking region a4 of the second mask pattern 13 are about 0.1% or less.

As shown in FIG. 5, in a case where a photoresist is exposed by using the mask 1 provided by the present embodiment, light will be diffracted when passing through the upper surface of the mask 1 and when passing through the lower surface of the mask 1, respectively.

Specifically, when irradiating onto the upper surface of the mask 1, light will be diffracted at an edge of each light blocking region a4 (i.e., an edge of each light transmissive region b4) of the first mask pattern 12. The propagation direction of part of light irradiating onto the upper surface of the mask 1 will deviate outwards due to the diffraction, and this part of light irradiates onto the light blocking regions a4 of the second mask pattern 13 on the lower surface of the mask 1 and is blocked by the light blocking regions a4 of the second mask pattern 13. The other part of light (other than said part of light) will keep the original propagation direction to irradiate onto the lower surface of the mask 1, and will pass through the light transmissive regions b4 of the second mask pattern 13 to irradiate onto corresponding regions of the photoresist.

When irradiating onto the lower surface of the mask 1, light will also be diffracted at an edge of each light blocking region a4 (i.e., an edge of each light transmissive region b4) of the second mask pattern 13. The propagation direction of part of light irradiating onto the lower surface of the mask 1 will deviate outwards due to the diffraction, and this part of light irradiates onto regions of the photoresist corresponding to the light blocking regions a4 of the second mask pattern 13. The other part of light will be blocked by the light blocking regions a4 of the second mask pattern 13. Thus, an intensity of light irradiating onto regions of the photoresist corresponding to the light blocking regions a4 of the second mask pattern 13 is reduced significantly, and thus regions of the photoresist corresponding to the light blocking regions a4 of the second mask pattern 13 cannot be exposed. The remaining part of light will keep the original propagation direction to irradiate onto regions of the photoresist corresponding to the light transmissive regions b4 of the second mask pattern 13.

As compared with the first embodiment, in the present embodiment, the light diffracted when passing through the upper surface of the mask 1 completely irradiates onto a corresponding light blocking region a4 of the second mask pattern 13 on the lower surface of the mask 1, and is blocked by the light blocking region a4 of the second mask pattern 13. Thus, an amount of light diffracted at the lower surface of the mask 1 can be reduced, and an intensity of light irradiating onto a region of the photoresist corresponding to a light blocking region a4 of the second mask pattern 13 can be reduced. As a result, a reduced region of the photoresist corresponding to a light blocking region a4 of the second mask pattern 13 is irradiated by light and can be exposed by the light. In this way, an amount by which a size of an exposed region of the photoresist exceeds a size of the light transmissive region (i.e., the light transmissive region b4 of the first mask pattern 12 or the light transmissive region b4 of the second mask pattern 13) of the mask 1 can be reduced, and the size of an exposed region of the photoresist is closer to that of the light transmissive region of the mask 1. Therefore, a pattern obtained after development is finer, which facilitates improvement of the accuracy of exposure and further refinement of an exposure process. This finally increases the pixel density of a display device.

In summary, the mask provided by the embodiments of the present invention has the first mask pattern 12 on its upper surface and the second mask pattern 13 on its lower surface, and can reduce an amount by which a size of an actually exposed region of a photoresist exceeds a size of the light transmissive region (i.e., the light transmissive region b2 of the first mask pattern 12 in the case of the first embodiment, and the light transmissive region b4 of the first mask pattern 12 or the light transmissive region b4 of the second mask pattern 13 in the case of the second embodiment; the same is applicable to the following description and will not be repeatedly described) of the mask 1, thereby allowing a size of an exposed region of a photoresist to be closer to that of the light transmissive region of the mask 1, making a pattern obtained after development finer, and facilitating further refinement of an exposure process.

Another embodiment of the present invention provides a manufacturing method of a mask, and the mask is the mask provided by any one of the above embodiments. In the present embodiment, the manufacturing method includes:

a step of forming a first mask pattern on a surface (e.g., the upper surface) of a base substrate, such that the first mask pattern comprises light transmissive regions and light blocking regions; and

a step of forming a second mask pattern on an opposite surface (e.g., the lower surface) of the base substrate opposite to the surface where the first mask pattern is located, such that the second mask pattern comprises light transmissive regions and light blocking regions, and a projection of each light transmissive region of the first mask pattern on a plane where the second mask pattern is located being outside a corresponding light blocking region of the second mask pattern.

The mask manufactured by the manufacturing method provided by the present embodiment can reduce an amount by which a size of an actually exposed region of a photoresist exceeds a size of the light transmissive region of the mask, thereby allowing a size of an exposed region of a photoresist to be closer to that of the light transmissive region of the mask, making a pattern obtained after development finer, and facilitating further refinement of an exposure process.

Optionally, the projection of each light transmissive region of the first mask pattern on the plane where the second mask pattern is located coincides with a corresponding light transmissive region of the second mask pattern. Thus, it is possible to block, to the greatest extent, light diffracted at a boundary between the light blocking region and the light transmissive region of the first mask pattern at a surface (e.g., the upper surface) of the mask where the first mask pattern is located, thereby increasing the accuracy of an exposure process.

Another embodiment of the present invention provides an exposure apparatus. In the present embodiment, the exposure apparatus includes the mask provided by any one of the foregoing embodiments of the present invention.

The exposure apparatus provided by the present embodiment includes the mask provided by any one of the embodiments of the present invention, and thus can reduce an amount by which a size of an actually exposed region of a photoresist exceeds a size of the light transmissive region of the mask, thereby allowing a size of an exposed region of a photoresist to be closer to that of the light transmissive region of the mask, making a pattern obtained after development finer, and facilitating further refinement of an exposure process.

It should be understood that, the foregoing embodiments are only exemplary embodiments used for explaining the principle of the present invention, but the present invention is not limited thereto. Various variations and improvements may be made by a person skilled in the art without departing from the protection scope of the present invention, and these variations and improvements also fall into the protection scope of the present invention.

What is claimed is:

1. A mask, comprising:
a base substrate;
a first mask pattern formed on an upper surface of the base substrate; and
a second mask pattern formed on a lower surface of the base substrate;
wherein, the first mask pattern comprises a light transmissive region and a light blocking region, the second mask pattern comprises a light transmissive region and a light blocking region, a projection of the light transmissive region of the first mask pattern on a plane where the second mask pattern is located is outside the light blocking region of the second mask pattern, and the light blocking region of the second mask pattern is capable of blocking at least part of light diffracted at a boundary between the light blocking region and the light transmissive region of the first mask pattern, to prevent the at least part of light from emitting from the light transmissive region of the second mask pattern.

2. The mask according to claim 1, wherein, the projection of the light transmissive region of the first mask pattern on the plane where the second mask pattern is located coincides with the light transmissive region of the second mask pattern.

3. The mask according to claim 1, wherein, both the first mask pattern and the second mask pattern are formed by a photolithography process.

4. The mask according to claim 1, wherein, the light blocking region of the first mask pattern has a low light reflectivity, or the light blocking region of the second mask pattern has a low light reflectivity.

5. The mask according to claim 1, wherein, both the light blocking region of the first mask pattern and the light blocking region of the second mask pattern have a low light reflectivity.

6. The mask according to claim 1, wherein, both the light blocking region of the first mask pattern and the light blocking region of the second mask pattern are made of a metal oxide.

7. The mask according to claim 2, wherein, both the light blocking region of the first mask pattern and the light blocking region of the second mask pattern are made of a metal oxide.

8. The mask according to claim 3, wherein, both the light blocking region of the first mask pattern and the light blocking region of the second mask pattern are made of a metal oxide.

9. The mask according to claim 4, wherein, both the light blocking region of the first mask pattern and the light blocking region of the second mask pattern are made of a metal oxide.

10. The mask according to claim 5, wherein, both the light blocking region of the first mask pattern and the light blocking region of the second mask pattern are made of a metal oxide.

11. The mask according to claim 6, wherein, both the light blocking region of the first mask pattern and the light blocking region of the second mask pattern are made of chromium oxide.

12. The mask according to claim 7, wherein, both the light blocking region of the first mask pattern and the light blocking region of the second mask pattern are made of chromium oxide.

13. The mask according to claim 8, wherein, both the light blocking region of the first mask pattern and the light blocking region of the second mask pattern are made of chromium oxide.

14. The mask according to claim 9, wherein, both the light blocking region of the first mask pattern and the light blocking region of the second mask pattern are made of chromium oxide.

15. The mask according to claim 10, wherein, both the light blocking region of the first mask pattern and the light blocking region of the second mask pattern are made of chromium oxide.

16. A manufacturing method of the mask according to claim 1, comprising steps of:
forming a first mask pattern on a surface of a base substrate, such that the first mask pattern comprises a light transmissive region and a light blocking region; and
forming a second mask pattern on an opposite surface of the base substrate opposite to the surface where the first mask pattern is located, such that the second mask pattern comprises a light transmissive region and a light blocking region, and a projection of the light transmissive region of the first mask pattern on a plane where the second mask pattern is located is outside the light blocking region of the second mask pattern.

17. The manufacturing method according to claim 16, wherein, the projection of the light transmissive region of the first mask pattern on the plane where the second mask pattern is located coincides with the light transmissive region of the second mask pattern.

18. An exposure apparatus, comprising the mask according to claim 1.
